(19) United States
(12) Patent Application Publication
(10) Pub. No.: US 2014/0247558 A1
(43) Pub. Date: Sep. 4, 2014

(54) HEAT DISSIPATION DEVICE OF ELECTRONIC APPARATUS

(71) Applicant: CHE-YUAN WU, NEW TAIPEI CITY (TW)

(72) Inventor: CHE-YUAN WU, NEW TAIPEI CITY (TW)

(21) Appl. No.: 13/875,410

(22) Filed: May 2, 2013

(30) Foreign Application Priority Data
Mar. 4, 2013 (TW) 102203950

(51) Int. Cl. H05K 7/20

(52) U.S. Cl. CPC H05K 7/20509
USPC 361/704

(57) ABSTRACT

A heat dissipation device of electronic apparatus, which is applicable to an electronic apparatus with a heat source for dissipating heat. The heat dissipation device includes: at least one electroconductive heat conduction plate assembly having a contact face in contact with a grounding surface and a heat conduction face facing the heat source; and a heat spreader with an area smaller than that of the heat conduction plate assembly. The heat spreader is able to transversely conduct heat. The heat spreader is attached to the heat conduction plate assembly. The heat spreader has a proximal-to-heat-source section proximal to the heat source and a distal-from-heat-source section extending in a direction away from the heat source. The heat conduction plate assembly and the heat spreader cooperate with each other to conduct and spread the heat of the heat source in different directions.

### BACKGROUND OF THE INVENTION

1. Field of the Invention

The present invention relates generally to a heat dissipation device of electronic apparatus, and more particularly to a heat dissipation device, which is able to quickly and uniformly dissipate the heat generated by a heat source of the electronic apparatus so as to avoid accumulation of the heat around a local section and abnormal rise of the temperature thereof.

2. Description of the Related Art

Along with continuous advance of electronic sciences and technologies, various electronic products are more and more widely used. The electronic products include all kinds of electronic components (such as central processor, light-emitting elements, power transistors and the like components) to provide complicated and sophisticated video/audio effect in operation. In use of the electronic products, the electronic components will inevitably generate a great amount of heat. In the case that the heat is not efficiently dissipated, the heat will accumulate around the heat source to cause overheating of a local part of the surface of the case. Conventionally, a heat conduction member (such as a heat pipe) with better thermal conductivity is generally used to partially contact the heat source. In addition, a heat dissipation assembly (such as a radiating fin assembly and cooling fan) are disposed on the heat conduction member. The heat conduction member can transfer the heat of the heat source to the heat dissipation assembly to dissipate the heat. In this case, the heat is prevented from concentrating so that the abnormal rise of the temperature of a local section can be avoided.

However, the heat conduction member (heat pipe) and the heat dissipation assembly (radiating fin assembly and cooling fan) have a considerably complicated structure and are manufactured at quite high cost. Therefore, it is uneconomic to apply these components to the electronic products.

It is therefore tried by the applicant to provide a heat dissipation device of electronic apparatus to overcome the above problem. The heat dissipation device has simple structure and is manufactured at lower cost and is able to quickly and uniformly dissipate the heat generated by a heat source of the electronic apparatus so as to avoid concentration of the heat and abnormal rise of the temperature of a local section.

### SUMMARY OF THE INVENTION

It is therefore a primary object of the present invention to provide a heat dissipation device of electronic apparatus, which is able to quickly spread and outward dissipate the heat from a heat source so as to avoid concentration of the heat and abnormal rise of the temperature of a local section of the electronic apparatus.

It is a further object of the present invention to provide the above heat dissipation device of electronic apparatus, in which no expensive heat conduction component is used so that the manufacturing cost is lowered to promote the economic efficiency.

To achieve the above and other objects, the heat dissipation device of electronic apparatus of the present invention includes an electronic apparatus case having a heat source, at least one heat conduction plate assembly having at least one electroconductive heat conduction plate, and at least one heat spreader, which is able to quickly conduct heat along the surface. The heat spreader is attached to and in contact with the heat conduction plate assembly, The heat spreader has a proximal-to-heat-source section proximal to the heat source and a distal-from-heat-source section extending in a direction away from the heat source. At least one of the heat conduction plate assembly and the heat spreader is adjacent to the heat source.

In the above heat dissipation device of electronic apparatus, the heat conduction plate assembly includes at least two heat conduction plates. The heat spreader is disposed between the heat conduction plates in contact with the heat conduction plates.

In the above heat dissipation device of electronic apparatus, the heat spreader has an area smaller than that of the heat conduction plates.

In the above heat dissipation device of electronic apparatus, the heat spreader is an elongated plate body.

In the above heat dissipation device of electronic apparatus, the heat spreader has an elongated main extension section and at least one branch section obliquely extending from one side of the main extension section.

in the above heat dissipation device of electronic apparatus, the heat spreader has an elongated main extension section and at least one branch section obliquely extending from each of two sides of the main extension section.

In the above heat dissipation device of electronic apparatus, the branch sections obliquely extend in a direction away from the heat source and the main extension section.

In the above heat dissipation device of electronic apparatus, the electronic apparatus includes a case having a receiving space. The heat source is disposed in the receiving space.

In the above heat dissipation device of electronic apparatus, the heat conduction plate assembly has a contact face in contact with the case and an electroconductive adhesive layer is disposed between the heat conduction plate assembly and the case.

In the above heat dissipation device of electronic apparatus, an electroconductive adhesive layer is disposed between the heat conduction plate assembly and the heat spreader.

In the above heat dissipation device of electronic apparatus, there are two heat conduction plate assemblies respectively disposed in adjacency to upper and lower sides of the heat source of the electronic apparatus.

The present invention can be best understood through the following description and accompanying drawings, wherein:

### BRIEF DESCRIPTION OF THE DRAWINGS

FIG. 1 is a perspective exploded view of a first embodiment of the present invention;

FIG. 2 is a perspective partially assembled view of the first embodiment of the present invention;

FIG. 3 is a sectional assembled view of the first embodiment of the present invention;

FIG. 4 is a perspective exploded view of a second embodiment of the present invention;

FIG. 5 is a perspective exploded view of a third embodiment of the present invention;

FIG. 6 is a perspective exploded view of a fourth embodiment of the present invention;

FIG. 7 is a perspective partially assembled view of the fourth embodiment of the present invention;

FIG. 8 is a sectional assembled view of the fourth embodiment of the present invention;

FIG. 9 is a perspective exploded view of a fifth embodiment of the present invention; and

FIG. 10 is a perspective exploded view of a sixth embodiment of the present invention.

### DETAILED DESCRIPTION OF THE PREFERRED EMBODIMENTS

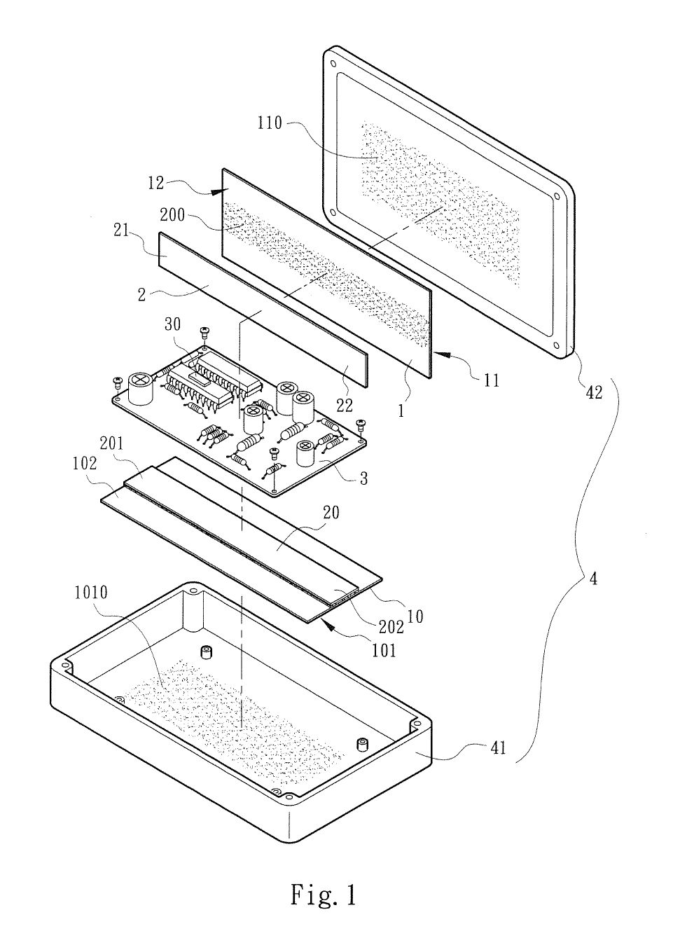

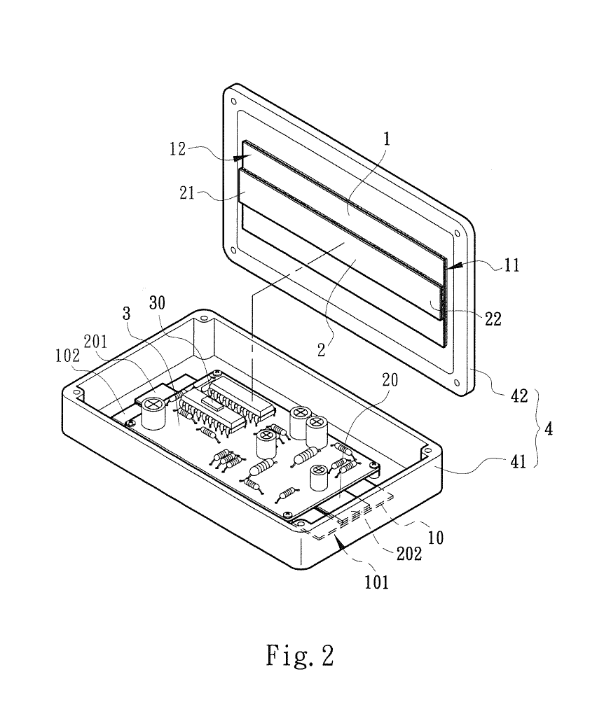

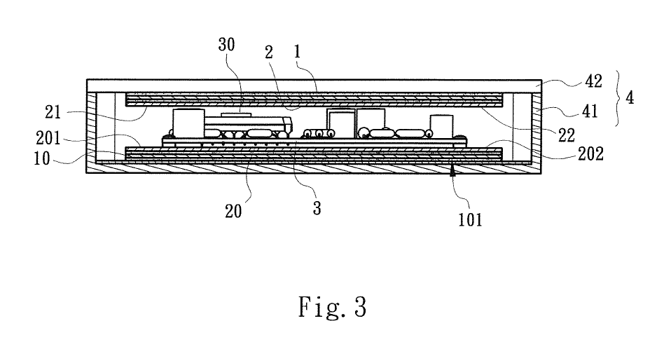

Please refer to FIGS. 1 to 3. According to a first embodiment, the heat dissipation device for electronic apparatus of the present invention includes a heat conduction plate assemblies 1, 10 and heat spreaders 2, 20. The heat conduction plate assembly 1 is one single heat conduction plate (made of metal material) with electroconductivity. The heat conduction plate assembly 10 is also one single heat conduction plate (made of metal material) with electroconductivity. Two faces of each heat conduction plate (heat conduction plate assembly 1, 10) are respectively provided with a contact face 11, 101 and a heat conduction face 12, 102. In practice, the heat conduction plate assemblies 1, 10 are applicable to a case 4 receiving a heat source 30. The surfaces of the heat conduction plate assemblies 1, 10 are partially adjacent to or in contact with the heat source 30. In this embodiment, the heat source 30 is an electronic component arranged on a circuit board 3, (such as a processor, a power transistor, etc.) The case 4 is composed of a case seat 41 for receiving the heat source 30 and a case cover 42 connected with an upper side of the case seat 41 to cover the heat source 30. (The case cover 42 can include a liquid crystal display screen). The contact faces 11, 101 of the heat conduction plate assemblies 1, 10 respectively attach to and contact inner surfaces of the case cover 42 (liquid crystal display screen) and the case seat 41. In addition, electroconductive adhesive layers 110, 1010 are disposed between the case cover 42 (liquid crystal display screen) and the case seat 41 and the contact faces 11, 101 to more securely and electrically connect the relevant components with each other for grounding or other designs.

The heat spreaders 2, 20 are plate-shaped structure bodies with an area smaller than that of the heat conduction plate assemblies 1, 10 (heat conduction plates) as necessary. The heat spreaders 2, 20 can be made of graphite or the like material. In this embodiment, the heat spreaders 2, 20 are elongated plate bodies having a property of quickly conducting heat along the surface (transversely). The heat spreaders 2, 20 are respectively attached to and in contact with the heat conduction plate assemblies 1, 10 (heat conduction plates). In practice, the heat spreaders 2, 20 can be electrical conductors. Electroconductive adhesive layers 200 can be disposed between the heat spreaders 2, 20 and the heat conduction plate assemblies 1, 10 (heat conduction plates) as necessary, whereby the heat spreaders 2, 20 and the heat conduction plate assemblies 1, 10 (heat conduction plates) are electrically connected with each other. Each of the heat spreaders 2, 20 has a proximal-to-heat-source section 21, 201 proximal to the heat source 30 and a distal-from-heat-source section 22, 202 extending in a direction away from the heat source 30.

In use, the heat generated by the heat source 30 is directly dissipated by way of radiation and air convection. Most of the upward transferred heat is conducted from the heat conduction face 12 into the heat conduction plate assembly 1 (heat conduction plate). Part of the heat is directly transferred to the heat spreader 2. The metal-made heat conduction plate 1 is able to radially uniformly spread the heat at equal speed and the heat conduction plate 1 is a thin sheet so that the heat very quickly passes through the heat conduction plate 1 and is transferred to the heat spreader 2. Due to the property of quickly conducting heat along the surface (transversely) of the heat spreader 2, the heat is quickly spread from the proximal-to-heat-source section 21 proximal to the heat source 30 to the distal-from-heat-source section 22 distal from the heat source 30. Then the heat is conducted from the heat spreader 2 back to the heat conduction plate assembly 1 (heat conduction plate). The heat of the heat source 30 not only is outward dissipated from the heat conduction plate assembly 1 (heat conduction plate), but also is partially conducted from the contact face 11 to the case cover 42 (liquid crystal display screen) and dissipated from the case cover 42. Similarly, the heat downward transferred by way of radiation or convection is conducted to the heat spreader 20 and conducted from the heat conduction face 102 into the heat conduction plate assembly 10 (heat conduction plate). The heat quickly passes through the heat conduction plate assembly 10 (heat conduction plate) and is transferred to the heat spreader 20. Due to the property of quickly conducting heat along the surface (transversely) of the heat spreader 20, the heat is quickly spread from the proximal-to-heat-source section 201 proximal to the heat source 30 to the distal-from-heat-source section 202 distal from the heat source 30. Then the heat is conducted from the heat spreader 20 back to the heat conduction plate assembly 10 (heat conduction plate). Accordingly, the heat of the heat source 30 not only is outward dissipated from the heat conduction plate assembly 10 (heat conduction plate), but also is partially conducted from the contact face 101 to the case seat 41 and dissipated from the case seat 41. Therefore, the heat is effectively prevented from accumulating in the case 4 around upper and lower sides of the heat source 30. In this case, the temperature of outer side of the case 4 will not locally abnormally rise.

In the above structure, as shown in the drawings, the heat spreaders 2, 20 are disposed on one side of the heat conduction plate assemblies 1, 10 (heat conduction plates), which side is proximal to the heat source 30. In practice, the heat spreaders 2, 20 can be alternatively disposed on one side of the heat conduction plate assemblies 1, 10 (heat conduction plates), which side is distal from the heat source 30. This can achieve the same heat dissipation effect. Also, in practice, the heat conduction plate assembly 1 or the heat conduction plate assembly 10 can be solely disposed in the case 4 in accordance with the actual requirements. It is unnecessary to dispose both the heat conduction plate assemblies 1, 10 in the case 4. Accordingly, the application is variable in accordance with different design requirements.

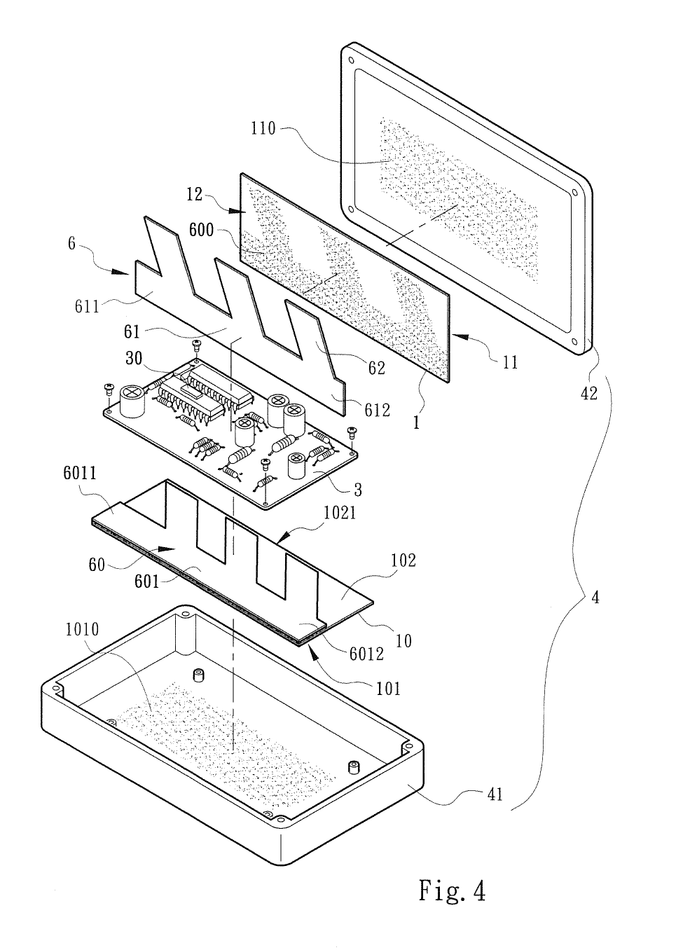

Please now refer to FIG. 4, which shows a second embodiment of the present invention. The second embodiment includes heat spreaders 6, 60 and heat conduction plate assemblies 1, 10 identical to that of the first embodiment. The heat conduction plate assemblies 1, 10 are disposed in the case 4 in the same manner as the first embodiment. Each the heat spreader 6, 60 is a plate-shaped structure body disposed on one side of the heat conduction plate assembly 1, 10 (heat conduction plate). An electroconductive adhesive layer 600 can be disposed between the heat conduction plate assembly 1, 10 (heat conduction plate) and the heat spreader 6, 60 as necessary. The heat spreader 6, 60 has an elongated main extension section 61, 601 and multiple branch sections 62, 602 obliquely extending from one side of the main extension section 61, 601 in parallel to each other. The branch sections 62, 602 obliquely extend in a direction away from the heat source 30 and the main extension section 61, 601. The main extension section 61, 601 has a proximal-to-heat-source section 611, 6011 proximal to the heat source 30 and a distal-from-heat-source section 612, 6012 extending in a direction away from the heat source 30.

In use, the heat generated by the heat source 30 is conducted to the heat conduction plate assemblies 1, 10 (heat conduction plates) and the heat spreaders 6, 60. The heat spreaders 6, 60 quickly spread the heat to those sections that are distal from the heat source 30 (to the distal-from-heat-source section 612, 6012 of the main extension sections 61, 601 and to the free ends of the branch sections 62, 602). Then the heat is partially outward dissipated from the heat conduction plate assemblies 1, 10 (heat conduction plates) and the rest of the heat is conducted from the contact faces 11, 101 to the case cover 42 (liquid crystal display screen) and the case seat 41 to dissipate. Therefore, the heat is effectively prevented from accumulating around the heat source 30. Also, the heat conduction plate assemblies 1, 10 and the heat spreaders 6, 60 can be grounded via the case 4.

In practice, as necessary, the heat spreaders 6, 60 can be disposed on one side of the heat conduction plate assemblies 1, 10 (heat conduction plates), which side is proximal to the heat source 30. Alternatively, the heat spreaders 6, 60 can be disposed on one side of the heat conduction plate assemblies 1, 10 (heat conduction plates), which side is distal from the heat source 30. Both can achieve the same heat dissipation effect.

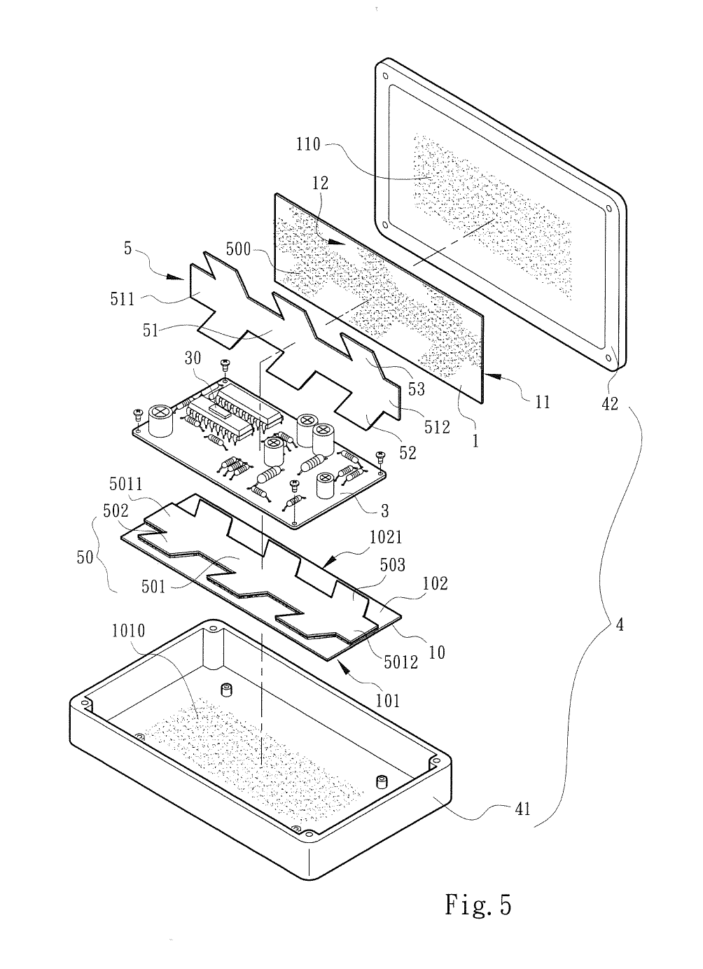

Please now refer to FIG. 5, which shows a third embodiment of the present invention. The third embodiment includes heat spreaders 5, 50 and heat conduction plate assemblies 1, 10 identical to that of the first embodiment. The heat conduction plate assemblies 1, 10 are disposed in the case 4 in the same manner as the first embodiment. Each the heat spreader 5, 50 is a plate-shaped structure body disposed on one side of the heat conduction plate assembly 1, 10 (heat conduction plate). An electroconductive adhesive layer 500 can be disposed between the heat conduction plate assembly 1, 10 (heat conduction plate) and the heat spreader 5, 50 as necessary. The heat spreader 5, 50 has an elongated main extension section 51, 501 and multiple branch sections 52, 53, 502, 503 obliquely extending from each of two sides of the main extension section 51, 501 in parallel to each other. The branch sections 52, 53, 502, 503 obliquely extend in a direction away from the heat source 30 and the main extension section 51, 501. The main extension section 51, 501 has a proximal-to-heat-source section 511, 5011 proximal to the heat source 30 and a distal-from-heat-source section 512, 5012 extending in a direction away from the heat source 30.

In use, the heat generated by the heat source 30 is conducted to the heat conduction plate assemblies 1, 10 (heat conduction plates) and the heat spreaders 5, 50. The heat spreaders 5, 50 quickly spread the heat to those sections that are distal from the heat source 30 (to the distal-from-heat-source section 512, 5012 of the main extension sections 61, 601 and to the free ends of the branch sections 52, 53, 502, 503). Then the heat is partially outward dissipated from the heat conduction plate assemblies 1, 10 (heat conduction plates) and the rest of the heat is conducted from the contact faces 11, 101 to the case cover 42 (liquid crystal display screen) and the case seat 41 to dissipate. Therefore, the heat is effectively prevented from accumulating around the heat source 30. Also, the heat conduction plate assemblies 1, 10 and the heat spreaders 5, 50 can be grounded via the case 4.

In practice, as necessary, the heat spreaders 5, 50 can be disposed on one side of the heat conduction plate assemblies 1, 10 (heat conduction plates), which side is proximal to the heat source 30. Alternatively, the heat spreaders 5, 50 can be disposed on one side of the heat conduction plate assemblies 1, 10 (heat conduction plates), which side is distal from the heat source 30. Both can achieve the same heat dissipation effect.

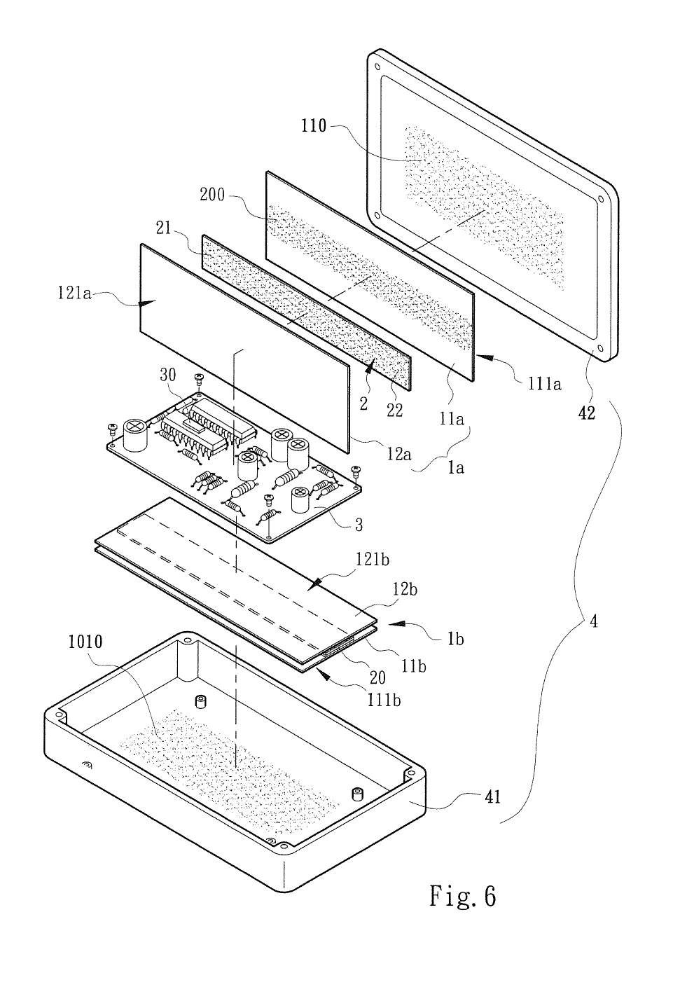

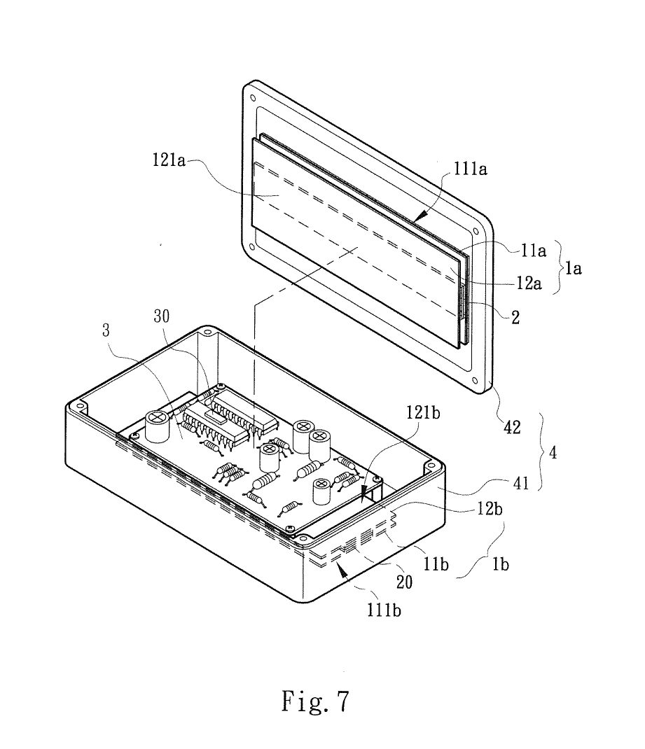

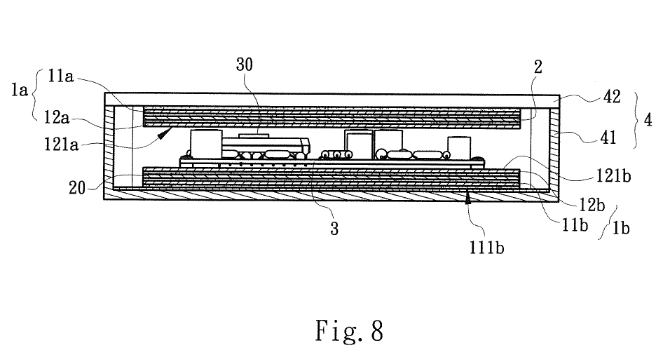

Please now refer to FIGS. 6 to 8, which show a fourth embodiment of the present invention. The fourth embodiment includes heat conduction plate assemblies 1a, 1b and heat spreaders 2, 20 identical to that of the first embodiment. Each of the heat conduction plate assemblies 1a, 1b includes two heat conduction plates 11a, 12a, 11b, 12b (made of metal material) with electroconductivity. A contact face 111a, 111b is formed on a face of the heat conduction plate 11a, 11b, which face is distal from the heat conduction plate 12a, 12b. A heat conduction face 121a, 121b is formed on a face of the heat conduction plate 12a, 12b, which face is distal from the heat conduction plate 11a, 11b. The heat conduction plate assemblies 1a, 1b are applicable to a case 4 receiving a heat source 30. The surfaces of the heat conduction plate assemblies 1a, 1b are partially adjacent to or in contact with the heat source 30. In this embodiment, the heat source 30 is an electronic component arranged on a circuit board 3, (such as a processor, a power transistor, etc.) The case 4 is composed of a case seat 41 for receiving the heat source 30 and a case cover 42 connected with an upper side of the case seat 41 to cover the heat source 30. (The case cover 42 can include a liquid crystal display screen). The contact faces 111a, 111b of the heat conduction plate assemblies 1a, 1b respectively attach to and contact inner surfaces of the case cover 42 (liquid crystal display screen) and the case seat 41. In addition, electroconductive adhesive layers 110, 1010 are disposed between the case cover 42 (liquid crystal display screen) and the case seat 41 and the contact faces 111a, 111b to more securely and electrically connect the relevant components with each other for grounding or other designs.

The heat spreaders 2, 20 are plate-shaped structure bodies with an area smaller than that of the heat conduction plate assemblies 1a, 1b. The heat spreaders 2, 20 can be made of graphite or the like material. In this embodiment, the heat spreader 2 is an elongated plate bodies having a property of quickly conducting heat along the surface (transversely). The heat spreader 2 is disposed between the heat conduction plates 11a, 12a of the heat conduction plate assembly 1a and attached to and in contact with the heat conduction plates 11a, 12a. In practice, the heat spreader 2 can be an electrical conductor. Electroconductive adhesive layers 200 can be disposed between the heat spreader 2 and the heat conduction plates 11a, 12a as necessary, whereby the heat spreader 2 and the heat conduction plates 11a, 12a are electrically connected with each other. The heat spreader 2 has a proximal-to-heat-source section 21 proximal to the heat source and a distal-from-heat-source section 22 extending in a direction away from the heat source. The heat spreader 20 is connected between the heat conduction plates 11b, 12b of the heat conduction plate assembly 1b in the same manner.

In use, the heat generated by the heat source 30 is directly dissipated by way of radiation and air convection. Most of the upward transferred heat is conducted from the heat conduction faces 121a, 121b into the heat conduction plates 12a, 12b of the heat conduction plate assemblies 1a, 1b. The metal-made heat conduction plates 12a, 12b are able to radially uniformly spread the heat at equal speed and the heat conduction plates 12a, 12b are thin sheets so that the heat very quickly passes through the heat conduction plates 12a, 12b and is transferred to the heat spreaders 2, 20. Due to the property of quickly conducting heat along the surface (transversely) of the heat spreaders 2, 20, the heat is quickly spread from the proximal-to-heat-source section 21 proximal to the heat source 30 to the distal-from-heat-source section 22 distal from the heat source 30. Then the heat is conducted from the heat spreaders 2, 20 back to the heat conduction plates 11a, 12a, 11b, 12b. Accordingly, the heat of the heat source 30 can be outward dissipated from the heat conduction plates 11a, 12a, 11b, 12b. Therefore, the heat is effectively prevented from accumulating in the case 4 around upper and lower sides of the heat source 30. In this case, the temperature of outer side of the case 4 will not locally abnormally rise.

In practice, the heat conduction plate assembly 1a or the heat conduction plate assembly 1b can be solely disposed in the case 4 in accordance with the actual requirements. It is unnecessary to dispose both the heat conduction plate assemblies 1a, 1b in the case 4. Accordingly, the application is variable in accordance with different design requirements.

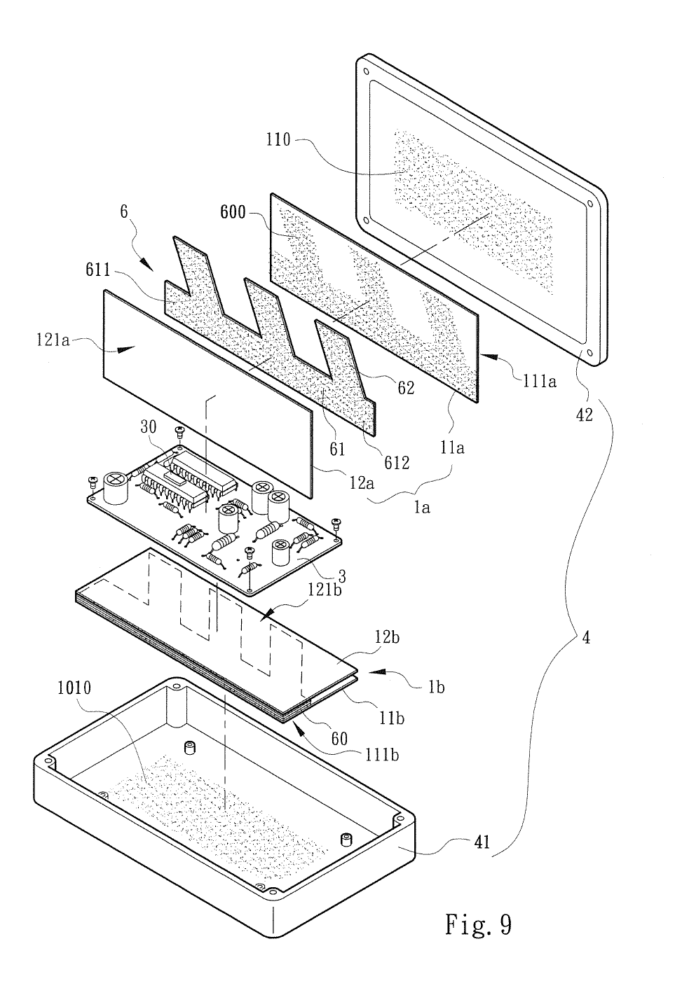

Please now refer to FIG. 9, which shows a fifth embodiment of the present invention. The fifth embodiment includes heat spreaders 6, 60 and heat conduction plate assemblies 1a, 1b identical to that of the fourth embodiment. The heat conduction plate assemblies 1a, 1b are disposed in the case 4 in the same manner. Each the heat spreader 6, 60 is a plate-shaped structure body disposed between the heat conduction plates 11a, 12a, 11b, 12b. Electroconductive adhesive layers 600 can be disposed between the heat spreaders 6, 60 and the heat conduction plates 11a, 12a, 11b, 12b as necessary. Each the heat spreader 6, 60 has an elongated main extension section 61, 601 and multiple branch sections 62, 602 obliquely extending from one side of the main extension section 61, 601 in parallel to each other. The branch sections 62, 602 obliquely extend in a direction away from the heat source 30 and the main extension section 61, 601. The main extension section 61, 601 has a proximal-to-heat-source section 611, 6011 proximal to the heat source 30 and a distal-from-heat-source section 612, 6012 extending in a direction away from the heat source 30.

In use, the heat generated by the heat source 30 is directly dissipated by way of radiation and air convection. The heat is conducted from the heat conduction faces 121a, 121b into the heat conduction plates 12a, 12b of the heat conduction plate assemblies 1a, 1b. The heat spreaders 6, 60 quickly transversely conduct the heat to quickly spread the heat from the sections proximal to the heat source 30 to the sections distal from the heat source 30, (that is, the distal-from-heat-source section 612 and the free ends of the branch sections 62, 602). Then the heat is conducted from the heat spreaders 6, 60 back to the heat conduction plates 11a, 12a, 11b, 12b. Accordingly, the heat of the heat source 30 can be outward dissipated from the heat conduction plates 11a, 12a, 11b, 12b. Therefore, the heat is effectively prevented from accumulating in the case 4 around upper and lower sides of the heat source 30. In this case, the temperature of outer side of the case 4 will not locally abnormally rise.

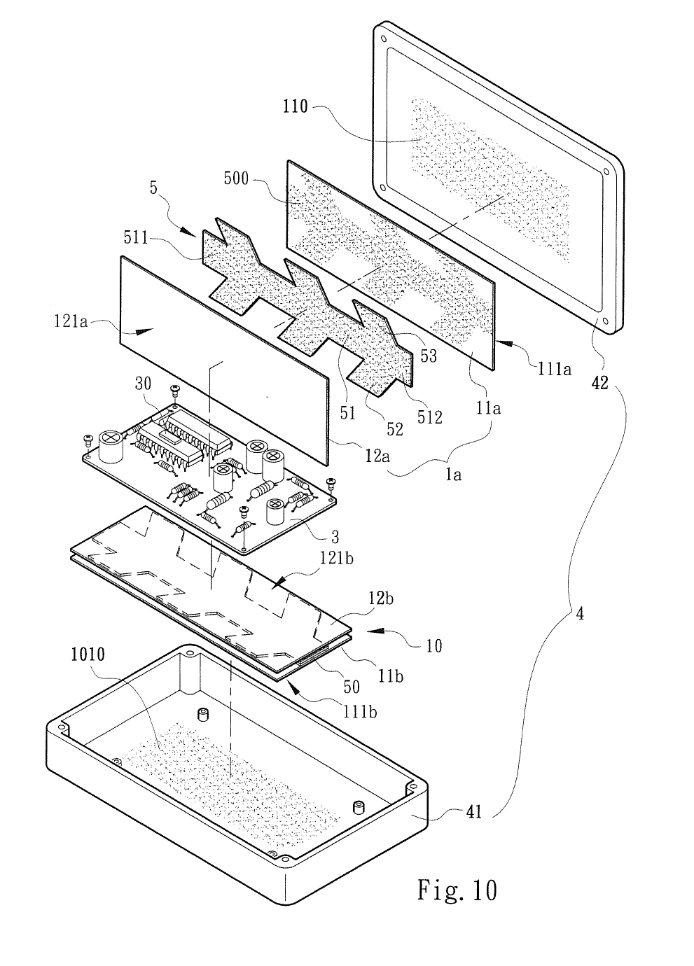

Please now refer to FIG. 10, which shows a sixth embodiment of the present invention. The sixth embodiment includes heat spreaders 5, 50 and heat conduction plate assemblies 1a, 1b identical to that of the fourth embodiment. The heat conduction plate assemblies 1a, 1b are disposed in the case 4 in the same manner. Each the heat spreader 5, 50 is a plate-shaped structure body disposed between the heat conduction plates 11a, 12a, 11b, 12b. Electroconductive adhesive layers 500 can be disposed between the heat spreaders 5, 50 and the heat conduction plates 11a, 12a, 11b, 12b as necessary. Each the heat spreader 5, 50 has an elongated main extension section 51, 501 and multiple branch sections 52, 53, 502, 503 obliquely extending from each of two sides of the main extension section 51, 501 in parallel to each other. The branch sections 52, 53, 502, 503 obliquely extend in a direction away from the heat source 30 and the main extension section 51, 501. The main extension section 51, 501 has a proximal-to-heat-source section 511, 5011 proximal to the heat source 30 and a distal-from-heat-source section 512, 5012 extending in a direction away from the heat source 30.

In use, the heat generated by the heat source 30 is directly dissipated by way of radiation and air convection. The heat is conducted from the heat conduction faces 121a, 121b into the heat conduction plates 12a, 12b of the heat conduction plate assemblies 1a, 1b. The heat spreaders 5, 50 quickly transversely conduct the heat to quickly spread the heat from the sections proximal to the heat source 30 to the sections distal from the heat source 30, (that is, the distal-from-heat-source section 512 and the free ends of the branch sections 52, 53, 502, 503). Then the heat is conducted from the heat spreaders 5, 50 back to the heat conduction plates 11a, 12a, 11b, 12b. Accordingly, the heat of the heat source 30 can be outward dissipated from the heat conduction plates 11a, 12a, 11b, 12b. Therefore, the heat is effectively prevented from accumulating in the case 4 around upper and lower sides of the heat source 30. In this case, the temperature of outer side of the case 4 will not locally abnormally rise.

In conclusion, the heat dissipation device of electronic apparatus of the present invention can quickly and uniformly dissipate the heat to avoid accumulation of the heat at lower manufacturing cost.

The above embodiments are only used to illustrate the present invention, not intended to limit the scope thereof. Many modifications of the above embodiments can be made without departing from the spirit of the present invention.

What is claimed is:

1. A heat dissipation device of electronic apparatus, comprising:
an electronic apparatus case having a heat source;
at least one heat conduction plate assembly having at least one electroconductive heat conduction plate; and
at least one heat spreader, which is able to quickly conduct heat along the surface, the heat spreader being attached to and in contact with the heat conduction plate assembly, the heat spreader having a proximal-to-heat-source section proximal to the heat source and a distal-from-heat-source section extending in a direction away from the heat source, at least one of the heat conduction plate assembly and the heat spreader being adjacent to the heat source.

2. The heat dissipation device of electronic apparatus as claimed in claim 1, wherein the heat conduction plate assembly includes at least two heat conduction plates, the heat spreader being disposed between the heat conduction plates in contact with the heat conduction plates.

3. The heat dissipation device of electronic apparatus as claimed in claim 2, wherein the heat spreader has an area smaller than that of the heat conduction plates.

4. The heat dissipation device of electronic apparatus as claimed in claim 1, wherein the heat spreader is an elongated plate body.

5. The heat dissipation device of electronic apparatus as claimed in claim 2, wherein the heat spreader is an elongated plate body.

6. The heat dissipation device of electronic apparatus as claimed in claim 3, wherein the heat spreader is an elongated plate body.

7. The heat dissipation device of electronic apparatus as claimed in claim 4, wherein the heat spreader has an elongated main extension section and at least one branch section obliquely extending from one side of the main extension section.

8. The heat dissipation device of electronic apparatus as claimed in claim 5, wherein the heat spreader has an elongated main extension section and at least one branch section obliquely extending from one side of the main extension section.

9. The heat dissipation device of electronic apparatus as claimed in claim 6, wherein the heat spreader has an elongated main extension section and at least one branch section obliquely extending from one side of the main extension section.

10. The heat dissipation device of electronic apparatus as claimed in claim 7, wherein the branch section obliquely extends in a direction away from the heat source and the main extension section.

11. The heat dissipation device of electronic apparatus as claimed in claim 8, wherein the branch section obliquely extends in a direction away from the heat source and the main extension section.

12. The heat dissipation device of electronic apparatus as claimed in claim 9, wherein the branch section obliquely extends in a direction away from the heat source and the main extension section.

13. The heat dissipation device of electronic apparatus as claimed in claim 4, wherein the heat spreader has an elongated main extension section and at least one branch section obliquely extending from each of two sides of the main extension section.

14. The heat dissipation device of electronic apparatus as claimed in claim 13, wherein the branch sections obliquely extend in a direction away from the heat source and the main extension section.

15. The heat dissipation device of electronic apparatus as claimed in claim 1, wherein the electronic apparatus includes a case having a receiving space, the heat source being disposed in the receiving space.

16. The heat dissipation device of electronic apparatus as claimed in claim 2, wherein the electronic apparatus includes a case having a receiving space, the heat source being disposed in the receiving space.

17. The heat dissipation device of electronic apparatus as claimed in claim 3, wherein the electronic apparatus includes a case having a receiving space, the heat source being disposed in the receiving space.

18. The heat dissipation device of electronic apparatus as claimed in claim 4, wherein the electronic apparatus includes a case having a receiving space, the heat source being disposed in the receiving space.

19. The heat dissipation device of electronic apparatus as claimed in claim 7, wherein the electronic apparatus includes a case having a receiving space, the heat source being disposed in the receiving space.

20. The heat dissipation device of electronic apparatus as claimed in claim 15, wherein the heat conduction plate assembly has a contact face in contact with the case, an electroconductive adhesive layer being disposed between the heat conduction plate assembly and the case.

21. The heat dissipation device of electronic apparatus as claimed in claim 16, wherein the heat conduction plate assembly has a contact face in contact with the case, an electroconductive adhesive layer being disposed between the heat conduction plate assembly and the case.

22. The heat dissipation device of electronic apparatus as claimed in claim 17, wherein the heat conduction plate assembly has a contact face in contact with the case, an electroconductive adhesive layer being disposed between the heat conduction plate assembly and the case.

23. The heat dissipation device of electronic apparatus as claimed in claim 18, wherein the heat conduction plate assembly has a contact face in contact with the case, an electroconductive adhesive layer being disposed between the heat conduction plate assembly and the case.

24. The heat dissipation device of electronic apparatus as claimed in claim 1, wherein an electroconductive adhesive layer is disposed between the heat conduction plate assembly and the heat spreader.

25. The heat dissipation device of electronic apparatus as claimed in claim 2, wherein an electroconductive adhesive layer is disposed between the heat conduction plate assembly and the heat spreader.

26. The heat dissipation device of electronic apparatus as claimed in claim 3, wherein an electroconductive adhesive layer is disposed between the heat conduction plate assembly and the heat spreader.

27. The heat dissipation device of electronic apparatus as claimed in claim 4, wherein an electroconductive adhesive layer is disposed between the heat conduction plate assembly and the heat spreader.

28. The heat dissipation device of electronic apparatus as claimed in claim 7, wherein an electroconductive adhesive layer is disposed between the heat conduction plate assembly and the heat spreader.

29. The heat dissipation device of electronic apparatus as claimed in claim 15, wherein an electroconductive adhesive layer is disposed between the heat conduction plate assembly and the heat spreader.

30. The heat dissipation device of electronic apparatus as claimed in claim 1, wherein there are two heat conduction plate assemblies respectively disposed in adjacency to upper and lower sides of the heat source of the electronic apparatus.

31. The heat dissipation device of electronic apparatus as claimed in claim 2, wherein there are two heat conduction plate assemblies respectively disposed in adjacency to upper and lower sides of the heat source of the electronic apparatus.

32. The heat dissipation device of electronic apparatus as claimed in claim 3, wherein there are two heat conduction plate assemblies respectively disposed in adjacency to upper and lower sides of the heat source of the electronic apparatus.

33. The heat dissipation device of electronic apparatus as claimed in claim 4, wherein there are two heat conduction plate assemblies respectively disposed in adjacency to upper and lower sides of the heat source of the electronic apparatus.

34. The heat dissipation device of electronic apparatus as claimed in claim 7, wherein there are two heat conduction plate assemblies respectively disposed in adjacency to upper and lower sides of the heat source of the electronic apparatus.

35. The heat dissipation device of electronic apparatus as claimed in claim 15, wherein there are two heat conduction plate assemblies respectively disposed in adjacency to upper and lower sides of the heat source of the electronic apparatus.

36. The heat dissipation device of electronic apparatus as claimed in claim 24, wherein there are two heat conduction plate assemblies respectively disposed in adjacency to upper and lower sides of the heat source of the electronic apparatus.
